(19) United States
(12) Patent Application Publication
(10) Pub. No.: US 2007/0105396 A1
(43) Pub. Date: May 10, 2007

(54) High resolution structures defined by brush painting fluid onto surface energy patterned substrates

(75) Inventors: Shunpu Li, Cambridgeshire (GB); Christopher Newsome, Cambridgeshire (GB); David Russell, Cambridgeshire (GB); Thomas Kugler, Cambridgeshire (GB)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 11/589,207

(22) Filed: Oct. 30, 2006

(30) Foreign Application Priority Data
Nov. 4, 2005 (GB) 0522584.2

(51) Int. Cl. H01L 21/31; H01L 21/469

(52) U.S. Cl. 438/758

(57) ABSTRACT

Disclosed is a method for fabricating an electronic device, the method comprising creating a surface energy pattern on a substrate and brush painting a first fluid onto the substrate to form a pattern of fluid corresponding to the surface energy pattern on the substrate. Also disclosed is a thin film transistor comprising a conductive layer, a layer of insulator formed on the conductive layer, a pattern of conductive material and a first self-assembled monolayer (SAM) formed on the layer of insulator, a second SAM formed on the conductive material, and a semiconductor layer formed on the first SAM and the second SAM. Further disclosed is a brush painting apparatus comprising an ink-absorbent brush head, an ink container connected to the brush head by an ink flow path and a conveyor belt, wherein a surface of the conveyor belt faces the brush head.

### BACKGROUND

An aspect of the present invention relates to a method for fabricating electronic devices, including but not limited to thin film transistors, by applying fluid to a substrate. The present invention also relates to a thin film transistor and a brush painting apparatus.

Electronics based on organic and inorganic solution-processable materials has attracted enormous research interest over the past few decades. These materials have proven their potential for use in a wide range of applications, such as light-emitting diodes (LEDs), photovoltaic cells and thin film transistors (TFTs). Recent developments in patterning technologies have further proven their potential for the manufacture of large area integrated devices on both rigid and flexible substrates. There exist several techniques to fabricate structures based on a solution process, such as screen printing, ink-jet printing and dip-coating on patterned substrates. The printing resolution of screen printing is very limited, and the frequent damage of masks used in the process leads to a high cost for this technique. Ink-jet printing is a very promising technique, but recently achieved free-format printing resolutions (˜50 μm) are still not sufficient to meet the requirements of the electronics industry. Dip-coating on a pre-patterned substrate is difficult to use in practical applications, because the flow of liquid over the substrate is hard to control. Any insufficiency or pile up of solvent can lead to failure of the patterning defined by dip-coating. Thus, to enable mass production of high resolution structures by a solution process, it is desirable to develop other patterning techniques.

Although there are many lithography techniques that can be used to fabricate high resolution structures, their multi-step nature and the associated alignment processes dramatically increase the cost of the fabrication process. An object of the invention is to provide a fast and cheap high resolution patterning method for the fabrication of electronic devices.

### SUMMARY OF THE INVENTION

According to a first aspect of the present invention, there is provided a method for fabricating an electronic device, the method comprising: creating a surface energy pattern on a substrate; and brush painting a first fluid onto the substrate to form a pattern of fluid corresponding to the surface energy pattern on the substrate.

The technique of the invention offers a cheap, fast, high resolution patterning method which allows different types of ink to be used to paint electronic devices on the same substrate. The brushing technique of the invention enables a pattern to be formed faster than is possible using ink-jet printing. Patterns involving multi-layered materials and chemical patterns in a continuous film can also be fabricated by this technique. In combination with ink-jet printing or other deposition techniques, the invention enables the fabrication of high resolution patterns of electronically functional materials for the production of electronic devices.

Preferably, the method further comprises depositing another structured layer on the substrate using ink-jet printing.

Preferably, the surface energy pattern comprises a material philic to the first fluid and a material phobic to the first fluid. Suitably, the philic material is hydrophilic, oleophilic or lyophilic and the phobic material is hydrophobic, oleophobic or lyophobic.

Preferably, the step of creating a surface energy pattern comprises depositing a first self-assembled monolayer (SAM) onto the substrate. Suitably, the first SAM is deposited using soft contact printing. Preferably, the first SAM comprises H1,H1,H2,H2-perfluorodecyltrichlorosilane.

In one embodiment, the first fluid comprises a conductive polymer. Suitably, the first fluid comprises poly(3,4-ethylene-dioxythiophene) (PEDOT) and poly(styrene sulphonic acid) (PSS).

In another embodiment, the first fluid comprises a metal. Suitably, the first fluid comprises one of Au, Ag, Cu, Al, Ni and Pt. Preferably, the first fluid comprises one of Ag and Au. Suitably, the method further comprises: annealing the substrate to form a pattern of the one of Ag and Au on the substrate; and depositing a second SAM on the pattern of the one of Ag and Au. Preferably, the second SAM comprises 1H,1H,2H,2H-perfluorodecanethiol.

In one embodiment, the method further comprises depositing a semiconductor layer over the substrate. Preferably, this method further comprises depositing a dielectric layer on the semiconductor layer. Suitably, this method further comprises depositing a pattern of conductive material on the dielectric layer.

In one embodiment, the substrate comprises a conductive layer and an insulating layer, and the step of forming a surface energy pattern comprises forming a surface energy pattern on the insulating layer.

Conveniently, the method further comprises: brush painting a second fluid onto the substrate to form a multi-layered pattern corresponding to the surface energy pattern on the substrate. Preferably, this method further comprises a step of curing the pattern of fluid either thermally or optically before the step of brush painting a second fluid onto the substrate.

Suitably, the first and second fluids are identical. Alternatively, the first and second fluids comprise different materials.

Preferably, the method further comprises: performing a surface treatment to change the polarity of the wetting contrast of the surface of the substrate after the step of brush painting; and brush painting a further fluid onto the substrate.

Suitably, the first fluid is brush painted onto the substrate in a first area of the substrate and another fluid is brush painted onto the substrate in a second area of the substrate, and the two fluids comprise different materials.

Preferably, features of the surface energy pattern are less than 1 mm in size. Suitably, material deposited by brush painting has a thickness between 10 nm and 10 μm. Preferably, brush painting is performed by moving the substrate at a speed from 0.001 m/s to 1 m/s relative to a brush head.

In one embodiment, there is provided a roll-to-roll or sheet-to-sheet process for fabricating electronic devices comprising a method as described above. In another embodiment, there is provided an electronic device fabricated by a method as described above.

According to a second aspect of the present invention, there is provided a thin film transistor comprising: a conductive layer; a layer of insulator formed on the conductive layer; a pattern of conductive material and a first self-assembled monolayer (SAM) formed on the layer of insulator; a second SAM formed on the conductive material; and a semiconductor layer formed on the first SAM and the second SAM.

The thin film transistor according to the present invention can be manufactured quickly and cheaply on a large scale using brush painting, and provides high performance.

Preferably, the semiconductor layer comprises a polymer material and the first SAM directs polymer chains in the semiconductor layer to be locally aligned. By directing the polymer chains to be locally aligned, the first SAM improves charge transfer in the polymer semiconductor layer.

Suitably, the semiconductor layer comprises P3HT and the first SAM comprises H1,H1,H2,H2-perfluorodecyltrichlorosilane.

Preferably, the second SAM increases the work function of the conductive material.

By acting to increase the work function of the conductive material, the second SAM improves charge transfer from the conductive material to the semiconductor layer, thus improving the performance of the TFT.

Suitably, the conductive material comprises silver and the second SAM comprises 1H,1H,2H,2H-perfluorodecanethiol.

According to a third aspect of the present invention, there is provided a brush painting apparatus comprising: an ink-absorbent brush head; an ink container connected to the brush head by an ink flow path; and a conveyor belt; wherein a surface of the conveyor belt faces the brush head.

Preferably, the surface of the conveyor belt is in contact with the brush head.

### DESCRIPTION OF THE DRAWINGS

Embodiments of the present invention will now be described by way of further example only and with reference to the accompanying drawings, in which:

FIG. 1 shows a TFT fabrication process according to an embodiment of the invention;

FIG. 2 illustrates typical microstructures produced by a brush painting method according to an embodiment of the invention;

FIG. 3 shows a brush painting deposition process according to an embodiment of the invention;

FIG. 4 illustrates a method for patterning a continuous film according to an embodiment of the invention;

FIG. 5 illustrates a substrate produced by a micro-brushing method according to an embodiment of the invention;

FIG. 6 shows a process according to an embodiment of the invention for fabricating a bottom-gate TFT; and

FIG. 7 shows output characteristics for a bottom-gate TFT fabricated by a method according to an embodiment of the invention.

### DESCRIPTION OF THE PREFERRED EMBODIMENT

In the structure fabrication method of an embodiment of the invention a substrate is first pre-patterned by soft-contact printing. Following the pre-patterning, a solution of functional materials is painted onto the substrate using brushing to define the first layer of a device with a high resolution (such as a TFT channel between source and drain electrodes). Subsequent structured layers, in which a relatively low fabrication resolution is tolerable (such as a gate electrode for a TFT), are defined by ink-jet printing.

The soft-contact printed pattern formed on the substrate has a large wetting contrast defining ink-receptive areas and ink repellent areas. When a liquid film is deposited by brushing, a de-wetting process on the ink-repellent areas causes a sharp division between ink-receptive areas on which ink is deposited and ink-repellent areas on which substantially no ink is deposited. As a result, a well-defined pattern is produced. The pattern can be used directly as a pattern of device components, or used as a template to transfer a pattern onto other materials.

In the following, a preferred embodiment of the invention is described. The preferred embodiment uses inks based on silver colloids and inks based on polymer colloids containing poly(3,4-ethyfene-dioxythiophene) (PEDOT) doped with poly(styrene sulphonic acid) (PSS).

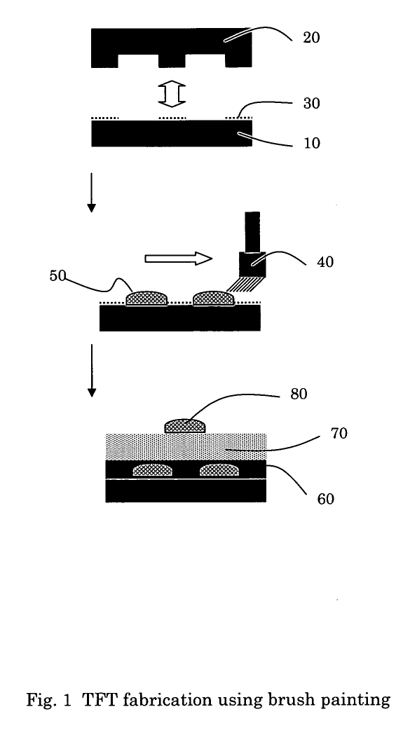

FIG. 1 shows a process for producing patterns by soft-contact printing and brush painting. Oxygen plasma treated silicon or glass is used as a substrate 10. Alternative substrate treatments include plasma etching, corona discharge treatment, UV-ozone treatment and wet-chemical treatment such as formation of a self-assembled molecular monolayer (SAM). Single-layer or multi-layer coatings can be formed on the substrate.

A structured polydimethylsiloxane (PDMS) stamp 20 is wetted for one minute using a solution of 0.005 mol H1,H1,H2,H2-perfluorodecyltrichlorosilane in hexane. After drying by nitrogen flow the stamp is brought into firm contact with the substrate for 30 s to form a self-assembled molecular monolayer (SAM) pattern 30 of H1,H1,H2,H2-perfluorodecyltrichlorosilane. However, any technique suitable for creating a surface energy pattern can be used to pre-pattern the substrate, including soft-contact printing, Photo-SAM lithography, micro-embossing, nanoimprinting, photolithography, optical interference and off-set printing.

Suitable SAM materials include molecules having a silane or thiol head group. The tail group of the molecules can be fluorine, alkyl, amino, hydroxyl or another group which is hydrophobic, lyophobic, hydrophilic or lyophilic depending on the substrate and ink solution. If it is intended for ink to be deposited on the regions of the substrate uncoated by the SAM, then the tail group of the SAM molecules must have a lower affinity for the ink than the substrate material. Conversely, if it is intended for ink to be deposited on the SAM, then the tail group of the SAM molecules must have a higher affinity for the ink than the substrate material. The surface energy pattern may comprise a plurality of SAM layers having different properties to allow a plurality of materials to be deposited onto the substrate by brush painting.

A brush 40, which is made from a natural fibre material such as paper or cotton, is dipped in PEDOT-PSS polymer or silver ink and is used to paint the ink onto the SAM pre-patterned substrate to define an ink pattern 50. The material used for the brush head must be capable of absorbing the ink and must also be soft enough not to damage the SAM layer. Micro-porous paper has been found to be a particularly suitable material for the brush head. It has been discovered that although a dry paper brush abrades and damages the SAM layer, a paper brush wetted with ink can be used without damaging the SAM layer.

In this context, the term brush is not limited to a head having bristles, but includes any flexible and absorbent member that can be used to deposit a fluid onto a surface. Similarly, the term brush painting includes brushing or wiping a surface using any such flexible and absorbent member in which fluid is absorbed.

In one embodiment, the brushing apparatus comprises an ink container and a brush head. The container is connected to the brush head by an ink flow path so that ink from the container is absorbed into the material of the brush head. The ink container may be positioned above the brush head so that ink flows from the container to the brush head under gravity. In other embodiments ink may be supplied to the brush head under pressure, by capillary action or by a siphon arrangement, in which case it is not necessary for the ink container to be above the brush head. The brush head is held stationary and a roll-to-roll conveyor belt is disposed beneath the brush head, the surface of the conveyor belt being pressed against or very close to the brush head. To perform brush painting, pre-patterned substrates are moved past the brush head on the conveyor belt so that the brush head moves over the substrate in contact with the upper surface of the substrate. However, in other embodiments a brush head can be moved over a stationary substrate or both head and substrate can move.

Suitable ink materials include soluble organic materials, soluble inorganic materials and colloidal suspensions based on water or other organic and inorganic solutions. The invention is generally applicable to a large range of inks for creating patterns of electrically functional material. Electrically functional materials include organic, inorganic or hybrid materials serving as conductors, semiconductors, or insulators.

During the brush painting process, the ink is held on the brush by capillary force, which depends on the wetting ability and the microstructure of the brush material. In principle, if the force of affinity between the substrate and the ink is larger than the capillary force holding the ink on the brush then the ink is transferred onto the substrate. Conversely, if the force of affinity between the substrate and ink is less than the capillary force then the ink remains on the brush. Accordingly, the force of affinity between the ink and either the coated or the uncoated areas of the substrate must be larger than the capillary force holding the ink on the brush in order for ink to be deposited. It is possible to create a pattern having a high wetting contrast by soft-contact printing. When the inked brush is drawn over such a pattern on the substrate, the areas with high wet-ability will accept the ink while the areas with low wet-ability will repel the ink.

The pressure of the brush on the substrate in the brush painting process of this embodiment is about 100 N/m², and the speed of the brush across the substrate is about 10 cm/s. However, brush pressures between 10 N/M² and 1000 N/M² and brushing speeds between 0.001 m/s and 1 m/s can be used.

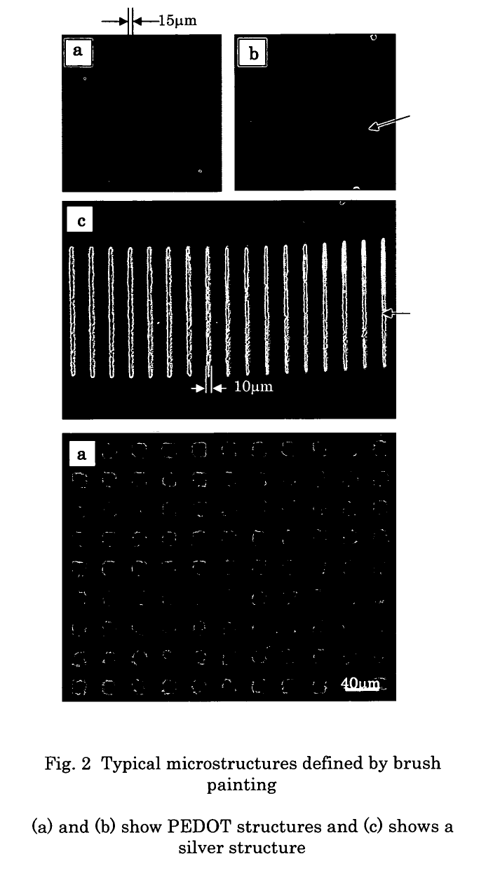

FIG. 2 shows typical PEDOT and silver structures defined by the above technique. It has been found that a resolution of less than 10 micrometers can be achieved over a large area. The thickness of the painted PEDOT and silver can be varied from a few tens of nanometres to a few microns depending on factors including ink concentration, brush speed, substrate components and surface roughness.

By combining the above patterning method with ink-jet printing it is possible to fabricate a polymer TFT such as that shown in FIG. 1. Pairs of strips of patterned PEDOT or silver form the source and drain electrodes of the TFT. A polymer such as polyarylamine (PAA), polythiophene, or poly 3-hexylthiophene (P3HT) is spin-coated on the patterned substrate to form the semiconductor layer 60. After baking for 30 min at 60° C. a dielectric layer 70 is spin coated on the top of the semiconductor layer 60. The dielectric layer can be formed from a polymer such as poly(4-vinylphenol) (PVP) or poly(4-methyl-1-pentene) (PMP). Typical layer thicknesses are 20 nm to 100 nm for semiconductors and 200 nm to 2000 nm for dielectrics. Layer thicknesses can be adjusted by altering the solvent concentration and the speed of spin-coating.

The soft-contact printed SAM layer can have a dual function when a polymer layer is deposited over the SAM layer. The SAM layer acts as a de-wetting layer to separate the painted materials, as described above, and also directs the chains of the polymer layer to align, which improves charge transfer in the polymer layer.

After another step of baking at 60° C. for 30 min, PEDOT-PSS is printed on the dielectric layer 70 to form the gate electrode 80, completing the TFT structure fabrication. Alternative techniques for depositing materials used as substrate coating layers and device components over the layer or layers deposited by brushing include doctor blading, printing (e.g. screen printing, offset printing, flexo printing, pad printing or inkjet printing), evaporation, sputtering, chemical vapour deposition, dip- and spray-coating, spin-coating and electroless plating. However, the combination of ink-jet printing technology with the brushing technique described above is particularly advantageous because the combined method allows electronic devices and integrated circuits to be produced quickly and cheaply over large areas. By using a brushing technique for portions of a device which benefit from a high resolution fabrication technique and using ink-jet printing for other portions of the device which are less sensitive to the resolution of the fabrication method, high performance devices can be produced on a large scale.

For silver source-drain electrodes a surface treatment is preferred to tune the work function of the electrodes. In the material combination above, the polymer semiconductors used are p-type and hence the source-drain electrodes must have a high work function to achieve good carrier injection from the electrodes 50 into the semiconductor layer 60. The treatment process used is:
(1) Anneal the brushed silver structure at 150° C. for one hour in nitrogen.
(2) Submerge the sample into a 0.005 mol solution of 1H,1H,2H,2H-perfluorodecanethiol in ethanol for 15 hours to form a 1H,1H,2H,2H-perfluorodecanethiol SAM layer on the silver.
(3) Dry the samples in a nitrogen flow.

An alternative method for treating the silver electrodes is to expose the electrodes to a CF₄ plasma.

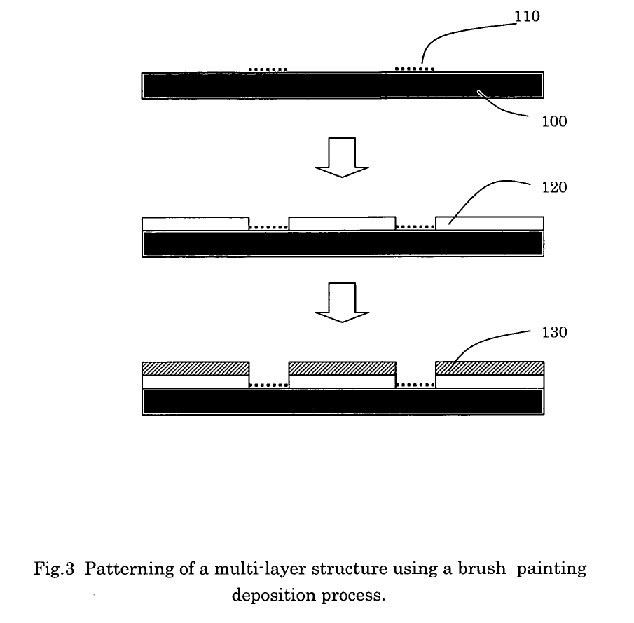

The brush painting patterning technique can also be used to pattern a multilayered structure, as shown in FIG. 3. In a first step a SAM pattern 110 is formed on a substrate 100, preferably using soft-contact printing as above. A first layer 120 is then deposited by brushing as above, the first layer 120 being deposited on portions of the substrate 100 not having the SAM pattern 110 formed thereon. The first layer 120 is cured thermally or optically to avoid the first layer 120 re-dissolving when a second layer 130 is applied. Subsequently, a second layer 130 is deposited on the first layer 120. The liquid used to deposit the second layer 130 must have an affinity with the surface of the first layer 120 and must be repelled by the SAM pattern 110.

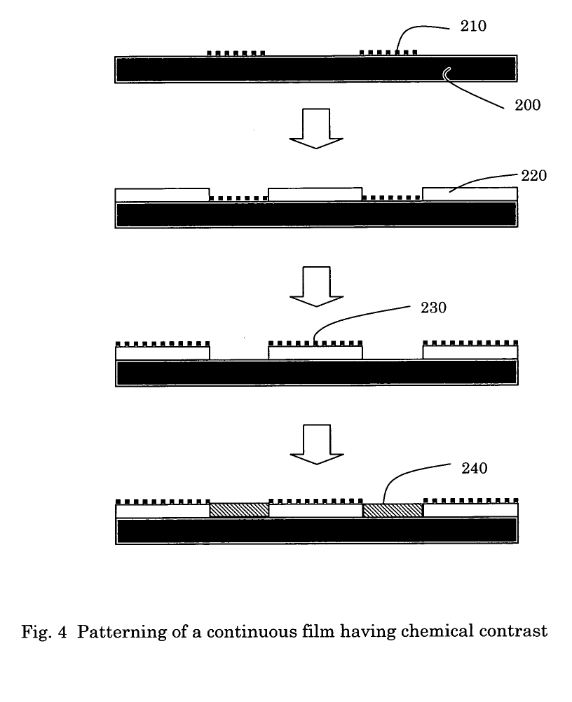

The brush painting technique can also be used to fabricate patterns having a chemical contrast in a continuous film, as illustrated in FIG. 4. A patterned SAM layer 210 is formed on a substrate 200. A patterned layer of first material 220 is then created by brush painting a material onto the substrate 200. Plasma or chemical treatment is applied to the substrate having the SAM layer 210 and the first material 220 formed thereon to change the polarity of the wetting contrast. Initially, the SAM layer 210 is repellent to the first material 220 so that the first material 220 is only deposited on areas of the substrate on which the SAM layer 210 is not formed. After the plasma or chemical treatment, the areas of the substrate on which the SAM layer 210 was formed are receptive to a second material 240 and the surface of the first material 220 is repellent to the second material 240.

For example, if a glass substrate 200 is used and the first material 220 is silver or gold, a CF₄ plasma treatment can be used to make the surface of the substrate 200 hydrophilic and the surface of the first material 220 hydrophobic. Finally, a patterned layer of the second material 240 is deposited by brush painting. The exposed areas of the substrate 200 accept the second material 240.

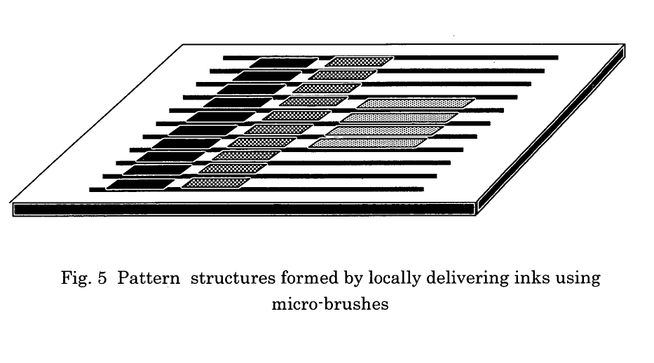

By scaling the brush used in the above brush painting technique to a small size, such as a few microns in width, it is possible to deposit different materials at different desired locations on the same substrate. A patterned substrate fabricated by such a micro-brushing technique is illustrated in FIG. 5. Thus various devices and circuits can be integrated on the same substrate using the above fabrication methods.

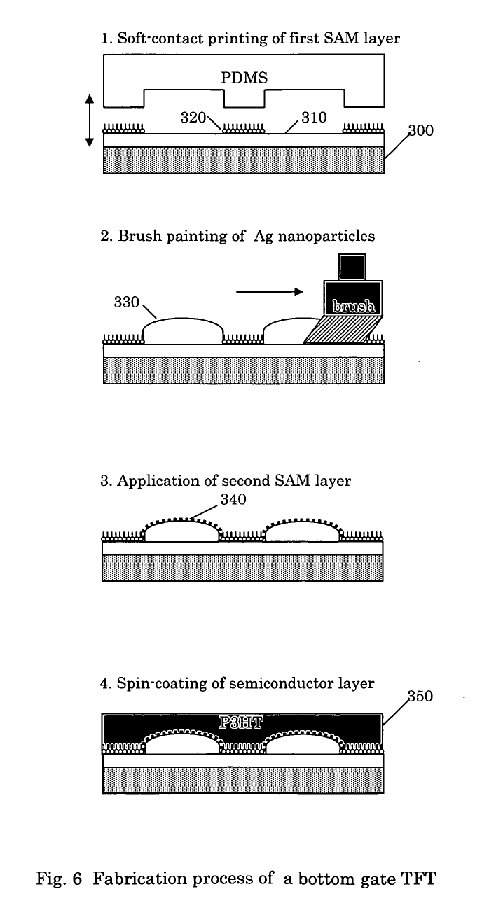

Another embodiment of the invention is a method for fabricating a bottom gate TFT, as shown in FIG. 6. A highly doped Si substrate 300 is used, having a 100 nm thick thermally oxidised top layer of SiO₂ 310. The doped Si layer 300 and the SiO₂ 310 layer act as gate and dielectric layers respectively. The substrate 300, 310 is cleaned in acetone, isopropanol (IPA), and O₂ plasma in sequence. Then a first SAM pattern 320 of H1,H1,H2,H2-perfluorodecyltrichlorosilane is created by soft-contact printing. After brush painting of a water based silver colloidal suspension 330, the sample is annealed at 150° C. for 1 hour.

The sample is submerged into a 0.005 mol solution of 1H,1H,2H,2H-perfluorodecanethiol in ethanol for 15 hours to form a 1H,1H,2H,2H-perfluorodecanethiol second SAM layer 340 on the silver 330, and is rinsed in ethanol, toluene and IPA. Rinsing is performed to remove crystals formed on the silver 330. After baking the sample at 60° C. for 10 min, a 40 nm thick layer of P3HT semiconductor polymer 350 is spin-coated on the top of the sample to complete the TFT.

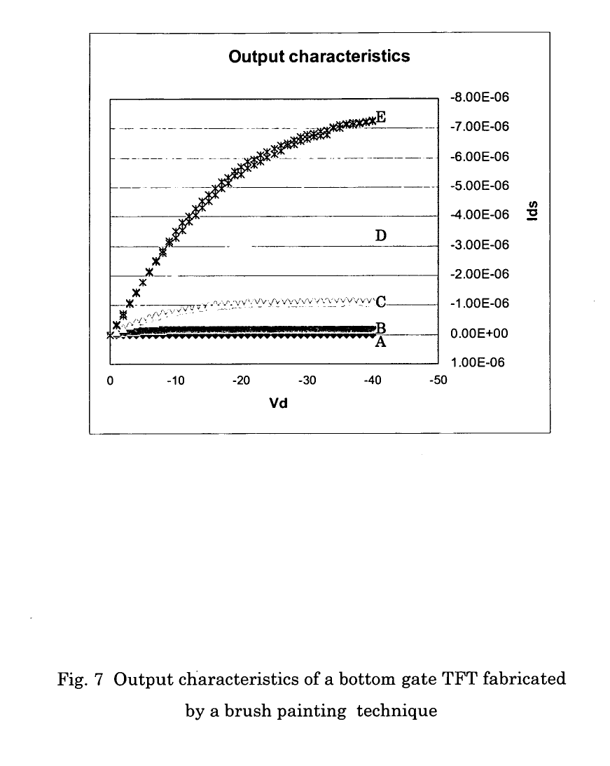

The first SAM layer 320 has a dual function in the formation of the TFT: it acts as a de-wetting layer to separate the brush painted silver suspension 330 into the desired pattern, and it also directs the P3HT polymer chains to be locally aligned, which improves charge transfer in the polymer layer. The second SAM layer 340 acts to increase the work function of the silver 330, thereby improving charge transfer from the silver electrodes 330 to the semiconductor polymer 350 and improving the performance of the TFT. FIG. 7 shows the measured current-voltage characteristics of a bottom gate TFT fabricated by the method of FIG. 6 described above. The gate voltages corresponding to the curves on the graph of FIG. 7 are set out in Table 1 below.

TABLE 1

| | Curve | | | | |
|---|---|---|---|---|---|
| | A | B | C | D | E |
| Gate Voltage (V) | 0 | −10 | −20 | −30 | −40 |

The TFT exhibits very high performance: the hole mobility is 2×10⁻² cm²V⁻¹S⁻¹ and the current on/off ratio is approximately 10⁵.

All of the processing steps described above can be implemented in either a batch or a continuous roll-to-roll production environment.

The aforegoing description has been given by way of example only and it will be appreciated by a person skilled in the art that modifications can be made without departing from the scope of the present invention.

1. A method for fabricating an electronic device, the method comprising:
creating a surface energy pattern on a substrate; and
brush painting a first fluid onto the substrate to form a pattern of fluid corresponding to the surface energy pattern on the substrate.

2. The method according to claim 1, further comprising depositing a structured layer on the substrate using ink-jet printing.

3. The method according to claim 1, wherein the surface energy pattern includes a material philic to the first fluid and a material phobic to the first fluid.

4. The method according to claim 3, wherein the philic material is hydrophilic, oleophilic or lyophilic and the phobic material is hydrophobic, oleophobic or lyophobic.

5. The method according to claim 1, wherein the creating of the surface energy pattern includes depositing a first self-assembled monolayer (SAM) onto the substrate.

6. The method according to claim 5, wherein the first SAM is deposited using soft contact printing.

7. The method according to claim 5, wherein the first SAM includes H1,H1,H2,H2-perfluorodecyltrichlorosilane.

8. The method according to claim 1, wherein the first fluid includes a conductive polymer.

9. The method according to claim 8, wherein the first fluid includes poly(3,4-ethylene-dioxythiophene) (PEDOT) and poly(styrene sulphonic acid) (PSS).

10. The method according to claim 1, wherein the first fluid includes a metal.

11. The method according to claim 10, wherein the first fluid includes one of Au, Ag, Cu, Al, Ni and Pt.

12. The method according to claim 11, wherein the first fluid includes one of Ag and Au.

13. The method according to claim 12, further comprising:
annealing the substrate to form a pattern of the one of Ag and Au on the substrate; and
depositing a second SAM on the pattern of the one of Ag and Au.

14. The method according to claim 13, wherein the second SAM includes 1H,1H,2H,2H-perfluorodecanethiol.

15. The method according to claim 1, further comprising depositing a semiconductor layer over the substrate.

16. The method according to claim 15, further comprising depositing a dielectric layer on the semiconductor layer.

17. The method according to claim 16, further comprising depositing a pattern of conductive material on the dielectric layer.

18. The method according to claim 1, wherein:
the substrate includes a conductive layer and an insulating layer; and
the forming of the surface energy pattern includes forming a surface energy pattern on the insulating layer.

19. The method according to claim 1, further comprising:
brush painting a second fluid onto the substrate to form a multi-layered pattern corresponding to the surface energy pattern on the substrate.

20. The method according to claim 19, further comprising a step of curing the pattern of fluid either thermally or optically before the brush painting of the second fluid onto the substrate.

21. The method according to claim 19, wherein the first and second fluids are identical.

22. The method according to claim 19, wherein the first and second fluids include different materials.

23. The method according to claim 1, further comprising:
performing a surface treatment to change the polarity of the wetting contrast of the surface of the substrate after the step of brush painting; and
brush painting a further fluid onto the substrate.

24. The method according to claim 1, wherein:
the first fluid is brush painted onto the substrate in a first area of the substrate and another fluid is brush painted onto the substrate in a second area of the substrate; and
the two fluids include different materials.

25. The method according to claim 1, wherein features of the surface energy pattern are less than 1 mm in size.

26. A method according to claim 1, wherein a material deposited by the brush painting of the first fluid has a thickness between 10 nm and 10 μm.

27. A method according to claim 1, wherein the brush painting of the first fluid is performed by moving the substrate at a speed from 0.001 m/s to 1 m/s relative to a brush head.

28. A roll-to-roll or sheet-to-sheet process for fabricating electronic devices comprising the method according to claim 1.

29. An electronic device fabricated by the method according to claim 1.

30. A thin film transistor comprising:
a conductive layer;
a layer of insulator formed on the conductive layer;
a pattern of conductive material and a first self-assembled monolayer (SAM) formed on the layer of insulator;
a second SAM formed on the conductive material; and
a semiconductor layer formed on the first SAM and the second SAM.

31. A thin film transistor according to claim 30, wherein the semiconductor layer comprises a polymer material and the first SAM directs polymer chains in the semiconductor layer to be locally aligned.

32. A thin film transistor according to claim 30, wherein the second SAM increases the work function of the conductive material.

33. A painting apparatus comprising:
an ink-absorbent brush head;
an ink container connected to the brush head by an ink flow path; and
a conveyor belt,
wherein a surface of the conveyor belt faces the brush head.

34. The brush painting apparatus according to claim 33, wherein the surface of the conveyor belt is in contact with the brush head.
